(19) United States
(12) Patent Application Publication
(10) Pub. No.: US 2025/0301560 A1
(43) Pub. Date: Sep. 25, 2025

(54) SOLID TARGET SUBSTANCE REPLENISHMENT DEVICE, EXTREME ULTRAVIOLET LIGHT GENERATION APPARATUS, AND ELECTRONIC DEVICE MANUFACTURING METHOD

(71) Applicant: Gigaphoton Inc., Tochigi (JP)

(72) Inventors: Yuto TANAKA, Oyama-shi (JP); Takuya ISHII, Oyama-shi (JP)

(73) Assignee: Gigaphoton Inc., Tochigi (JP)

(21) Appl. No.: 19/040,400

(22) Filed: Jan. 29, 2025

(30) Foreign Application Priority Data
Mar. 25, 2024 (JP) 2024-047485

(51) Int. Cl. H05G 2/00; G03F 1/22; G03F 7/00

(52) U.S. Cl. CPC H05G 2/002; G03F 1/22; G03F 7/70033

(57) ABSTRACT

A solid target substance replenishment device includes a solid target container containing a solid target substance; a first path through which the solid target substance supplied from the solid target container passes; a delivery device including a tube receiving the solid target substance having passed through the first path, a delivery rod delivering the solid target substance in the tube in a length direction thereof, and a drive unit reciprocating the delivery rod in the length direction; a second path through which the solid target substance delivered by the delivery device passes; and a funnel guiding, to a molten target container, the solid target substance having dropped thereto. The drive unit drives the delivery rod so that drop time difference is longer than 1.1 seconds when two or more solid target substances drop from the second path into the funnel by one reciprocal movement of the delivery rod.

### CROSS-REFERENCE TO RELATED APPLICATIONS

The present application claims the benefit of Japanese Patent Application No. 2024-047485, filed on Mar. 25, 2024, the entire contents of which are hereby incorporated by reference.

### BACKGROUND

### 1. Technical Field

The present disclosure relates to a solid target substance replenishment device, an extreme ultraviolet light generation apparatus, and an electronic device manufacturing method.

### 2. Related Art

Recently, miniaturization of a transfer pattern in optical lithography of a semiconductor process has been rapidly proceeding along with miniaturization of the semiconductor process. In the next generation, microfabrication at 10 nm or less will be required. Therefore, it is expected to develop an exposure apparatus that combines an extreme ultraviolet (EUV) light generation apparatus that generates EUV light having a wavelength of about 13 nm and reduced projection reflection optical system.

As the EUV light generation apparatus, a laser produced plasma (LPP) type apparatus using plasma generated by irradiating a target substance with laser light has been developed.

### LIST OF DOCUMENTS

### Patent Documents

Patent Document 1: US Patent Application Publication No. 2023/0008733
Patent Document 2: Japanese Patent Application Publication No. 2003-164553
Patent Document 3: Japanese Patent Application Publication No. 2005-249000

### SUMMARY

A solid target substance replenishment device according to an aspect of the present disclosure includes a solid target container configured to contain a solid target substance; a first path through which the solid target substance supplied from the solid target container passes; a delivery device including a tube that receives the solid target substance having passed through the first path, a delivery rod that delivers the solid target substance in the tube in a length direction of the tube, and a drive unit that reciprocates the delivery rod in the length direction of the tube; a second path through which the solid target substance delivered by the delivery device passes; and a funnel that guides, to a molten target container of an extreme ultraviolet light generation apparatus, the solid target substance having dropped after passing through the second path. Here, the drive unit drives the delivery rod so that drop time difference is longer than 1.1 seconds when two or more solid target substances drop from the second path into the funnel by one reciprocal movement of the delivery rod.

An electronic device manufacturing method according to an aspect of the present disclosure includes generating extreme ultraviolet light using an extreme ultraviolet light generation apparatus, outputting the extreme ultraviolet light to an exposure apparatus, and exposing a photosensitive substrate to the extreme ultraviolet light in the exposure apparatus to manufacture an electronic device. Here, the extreme ultraviolet generation apparatus includes a solid target substance replenishment device; a molten target container configured to melt a solid target substance replenished by the solid target substance replenishment device to produce a molten target substance; a nozzle configured to output the molten target substance produced in the molten target container; a laser device configured to irradiate, with pulse laser light, the molten target substance reaching a redetermined region after being output from the nozzle; and an EUV light concentrating mirror configured to concentrate extreme ultraviolet light emitted from plasma generated in the predetermined region. The solid target substance replenishment device includes a solid target container configured to contain the solid target substance; a first path through which the solid target substance supplied from the solid target container passes; a delivery device including a tube that receives the solid target substance having passed through the first path, a delivery rod that delivers the solid target substance inside the tube in a length direction of the tube, and a drive unit that reciprocates the delivery rod in the length direction of the tube; a second path through which the solid target substance delivered by the delivery device passes; and a funnel that guides, to the molten target container of an extreme ultraviolet light generation apparatus, the solid target substance having dropped after passing through the second path. The drive unit drives the delivery rod so that drop time difference is longer than 1.1 seconds when two or more solid target substances drop from the second path into the funnel by one reciprocal movement of the delivery rod.

An electronic device manufacturing method according to an aspect of the present disclosure includes inspecting a defect of a mask by irradiating the mask with extreme ultraviolet light generated by an extreme ultraviolet light generation apparatus, selecting a mask using a result of the inspection, and exposing and transferring a pattern formed on the selected mask onto a photosensitive substrate. Here, the extreme ultraviolet generation apparatus includes a solid target substance replenishment device; a molten target container configured to melt a solid target substance replenished by the solid target substance replenishment device to produce a molten target substance; a nozzle configured to output the molten target substance produced in the molten target container; a laser device configured to irradiate, with pulse laser light, the molten target substance reaching a redetermined region after being output from the nozzle; and an EUV light concentrating mirror configured to concentrate extreme ultraviolet light emitted from plasma generated in the predetermined region. The solid target substance replenishment device includes a solid target container configured to contain the solid target substance; a first path through which the solid target substance supplied from the solid target container passes; a delivery device including a tube that receives the solid target substance having passed through the first path, a delivery rod that delivers the solid target substance inside the tube in a length direction of the tube, and a drive unit that reciprocates the delivery rod in the length direction of the tube; a second path through which the solid target substance delivered by the delivery device passes; and a funnel that guides, to the molten target container of an extreme ultraviolet light generation apparatus, the solid target substance having dropped after passing through the second path. The drive unit drives the delivery rod so that drop time difference is longer than 1.1 seconds when two or more solid target substances drop from the second path into the funnel by one reciprocal movement of the delivery rod.

### BRIEF DESCRIPTION OF THE DRAWINGS

Embodiments of the present disclosure will be described below merely as examples with reference to the accompanying drawings.

FIG. 1 shows the configuration of an LPP EUV light generation system.

FIG. 2 shows the configuration of a droplet target generation device in the EUV light generation system according to a comparative example.

FIG. 3 shows the configuration and operation of a delivery device according to the comparative example.

FIG. 4 shows the configuration and operation of the delivery device according to the comparative example.

FIG. 5 shows the configuration and operation of the delivery device according to the comparative example.

FIG. 6 shows the configuration and operation of the delivery device according to the comparative example.

FIG. 7 shows how solid target substances move in response to reciprocal movement of a delivery rod.

FIG. 8 shows a funnel and a supply pipe for receiving the solid target substance having dropped from a discharge port and guiding the solid target substance to a molten target container.

FIG. 9 shows a first example in which two solid target substances drop into the funnel by one reciprocal movement of the delivery rod.

FIG. 10 is a graph showing drop timing of the solid target substances in the first example together with a cam curve of a cam.

FIG. 11 shows a second example in which two solid target substances drop into the funnel by one reciprocal movement of the delivery rod.

FIG. 12 is a graph showing the drop timing of the solid target substances in the second example together with the cam curve of the cam.

FIG. 13 shows the configuration of the cam and a cam follower of a first embodiment.

FIG. 14 is a graph showing the drop timing of the solid target substances in the first example in the first embodiment together with the cam curve of the cam.

FIG. 15 is a graph showing the drop timing of the solid target substances in the second example in the first embodiment together with the cam curve of the cam.

FIG. 16 shows the configuration of the droplet target generation device of a second embodiment.

FIG. 17 shows the configuration of an exposure apparatus connected to the EUV light generation system.

FIG. 18 shows the configuration of an inspection apparatus connected to the EUV light generation system.

### DESCRIPTION OF EMBODIMENTS

### <Contents>

1. Overall description of EUV light generation system 11
   1.1 Configuration
   1.2 Operation
2. Comparative example
   2.1 Configuration of droplet target generation device 26
      2.1.1 Solid target substance replenishment device 260
      2.1.2 Molten target container C3
      2.1.3 Nozzle 52
   2.2 Operation of droplet target generation device 26
   2.3 Configuration of delivery device 8
   2.4 Operation of delivery device 8
   2.5 Problem of comparative example
3. Solid target substance replenishment device 260 with drop time difference T_{ψ}-T_{ω} longer than 1.1 seconds
   3.1 Configuration of cam 841a
   3.2 Cam curve of cam 841a
   3.3 Effect
4. Solid target substance replenishment device 260c including detector D2
   4.1 Configuration
   4.2 Operation
   4.3 Effect
5. Others
   5.1 EUV light utilization apparatus 6
   5.2 Supplement

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Overall Description of EUV Light Generation System 11

### 1.1 Configuration

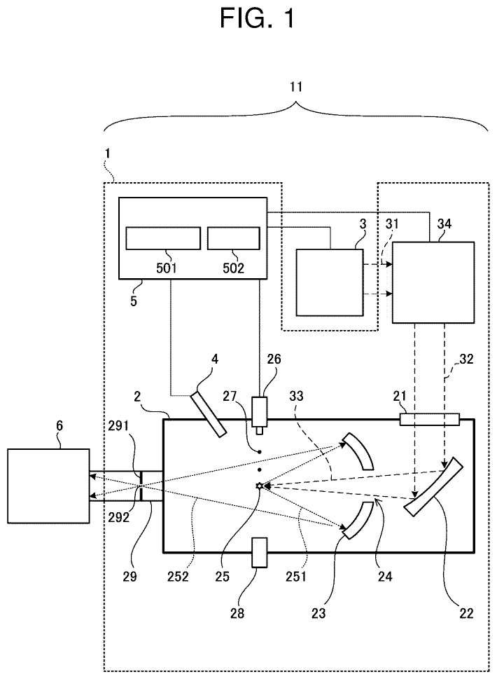

FIG. 1 shows the configuration of an LPP EUV light generation system 11. An EUV light generation apparatus 1 is used together with a laser device 3. In the present disclosure, a system including the EUV light generation apparatus 1 and the laser device 3 is referred to as the EUV light generation system 11. The EUV light generation apparatus 1 includes a chamber 2 and a droplet target generation device 26. The chamber 2 is a sealable container. The droplet target generation device 26 supplies a target 27 containing a target substance into the chamber 2. The material of the target substance may include tin, terbium, gadolinium, lithium, xenon, or a combination of any two or more thereof.

A through hole is formed in a wall of the chamber 2. The through hole is blocked by a window 21 and pulse laser light 32 output from the laser device 3 is transmitted through the window 21. An EUV light concentrating mirror 23 having a spheroidal reflection surface is arranged in the chamber 2. The EUV light concentrating mirror 23 has first and second focal points. A multilayer reflection film in which molybdenum and silicon are alternately stacked is formed on a surface of the EUV light concentrating mirror 23. The EUV light concentrating mirror 23 is arranged such that the first focal point is located in a plasma generation region 25 and the second focal point is located at an intermediate focal point 292. A through hole 24 is formed at the center of the EUV light concentrating mirror 23, and pulse laser light 33 passes through the through hole 24.

The EUV light generation apparatus 1 includes an EUV light generation processor 5, a target sensor 4, and the like. The EUV light generation processor 5 is a processing device including a memory 501 in which a control program is stored and a central processing unit (CPU) 502 that executes the control program. The EUV light generation processor 5 is specifically configured or programmed to perform various processes included in the present disclosure. The target sensor 4 detects at least one of the presence, trajectory, position, and velocity of the target 27. The target sensor 4 may have an imaging function.

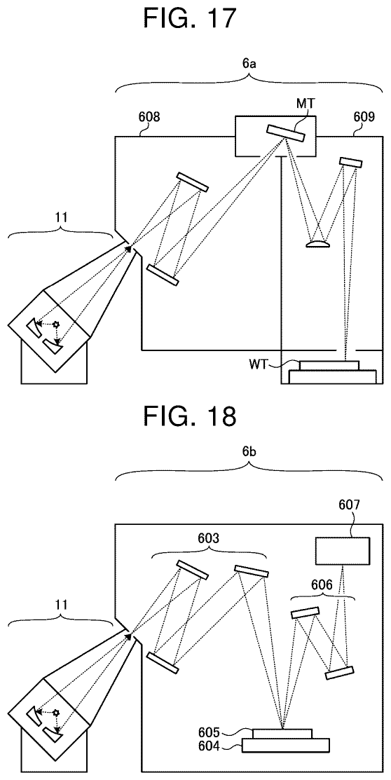

Further, the EUV light generation apparatus 1 includes a connection portion 29 providing communication between the internal space of the chamber 2 and the internal space of an EUV light utilization apparatus 6. The EUV light utilization apparatus 6 may be an exposure apparatus 6a shown in FIG. 17 or an inspection apparatus 6b shown in FIG. 18. A wall 291 in which an aperture is formed is arranged in the connection portion 29. The wall 291 is arranged such that the aperture is located at the second focal point of the EUV light concentrating mirror 23.

Further, the EUV light generation apparatus 1 includes a laser light transmission device 34, a laser light concentrating mirror 22, a target collection unit 28 for collecting the target 27, and the like. The laser light transmission device 34 includes an optical element for defining a transmission state of the pulse laser light 32, and an actuator for adjusting the position, posture, and the like of the optical element.

### 1.2 Operation

Operation of the EUV light generation system 11 will be described with reference to FIG. 1. Pulse laser light 31 output from the laser device 3 enters, via the laser light transmission device 34, the chamber 2 through the window 21 as the pulse laser light 32. The pulse laser light 32 travels along a laser light path in the chamber 2, is reflected by the laser light concentrating mirror 22, and is radiated to the target 27 as the pulse laser light 33.

The droplet target generation device 26 outputs the target 27 toward the plasma generation region 25 in the chamber 2. The target 27 is irradiated with the pulse laser light 33. The target 27 irradiated with the pulse laser light 33 is turned into plasma, and radiation light 251 is radiated from the plasma. The EUV light contained in the radiation light 251 is reflected by the EUV light concentrating mirror 23 with higher reflectance than light in other wavelength ranges. Reflection light 252 including the EUV light reflected by the EUV light concentrating mirror 23 is concentrated at the intermediate focal point 292 and output to the EUV light utilization apparatus 6. Here, one target 27 may be irradiated with a plurality of pulses included in the pulse laser light 33.

The EUV light generation processor 5 controls the entire EUV light generation system 11. The EUV light generation processor 5 processes a detection result of the target sensor 4. Based on the detection result of the target sensor 4, the EUV light generation processor 5 controls the timing at which the target 27 is output, the output direction of the target 27, and the like. Further, the EUV light generation processor 5 controls oscillation timing of the laser device 3, the travel direction of the pulse laser light 32, the concentration position of the pulse laser light 33, and the like. Such various kinds of control described above are merely exemplary, and other control may be added as necessary.

### 2. Comparative Example

### 2.1 Configuration of Droplet Target Generation Device 26

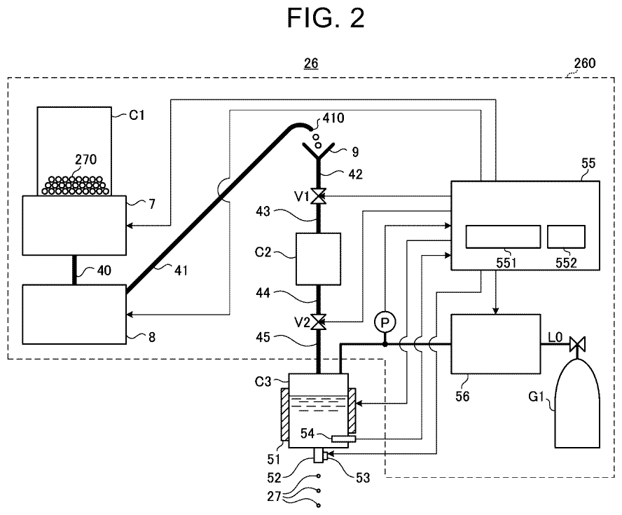

FIG. 2 shows the configuration of the droplet target generation device 26 in the EUV light generation system 11 according to the comparative example.

The comparative example of the present disclosure is an example recognized by the applicant as known only by the applicant, and is not a publicly known example admitted by the applicant. The droplet target generation device 26 includes a solid target substance replenishment device 260, a molten target container C3, and a nozzle 52.

### 2.1.1 Solid Target Substance Replenishment Device 260

The solid target substance replenishment device 260 includes a solid target container C1, a feed device 7, a delivery device 8, a funnel 9, a load lock chamber C2, a target supply processor 55, supply pipes 40 to 45, a gas cylinder G1, and a pressure regulator 56. The path of the solid target substance 270 configured by the feed device 7 and the supply pipe 40 corresponds to a first path through which the solid target substance 270 supplied from the solid target container C1 passes. The supply pipe 41 corresponds to a second path through which the solid target substance 270 delivered by the delivery device 8 passes.

The target supply processor 55 is a processing device including a memory 551 in which a control program is stored and a CPU 552 that executes the control program. The target supply processor 55 corresponds to the processor in the present disclosure. The target supply processor 55 is specifically configured or programmed to perform various processes included in the present disclosure.

The solid target container C1 is a container to contain the solid target substance 270 such as tin. The solid target substance 270 may be, for example, spherical particles of substantially the same size. The particle size of the solid target substance 270 is, for example, 2 mm or more and 5 mm or less. The particle size of the solid target substance 270 is, for example, a diameter of a perfect sphere having an equivalent volume. The temperature in the solid target container C1 is lower than the melting point of the target substance. The pressure in the solid target container C1 is about the same as the atmospheric pressure.

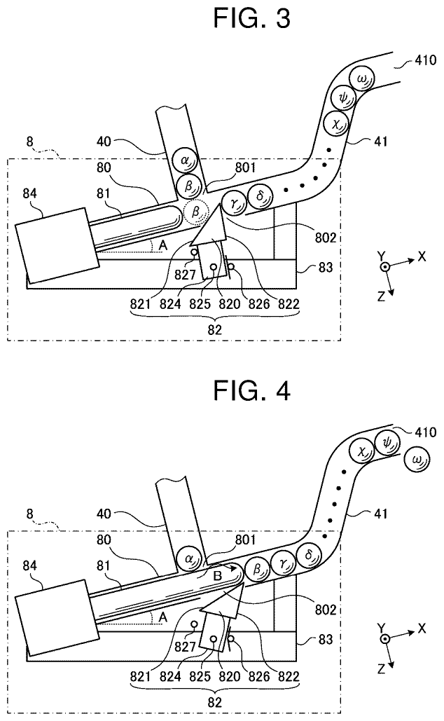

The feed device 7 is connected to the bottom of the solid target container C1, and connected to the delivery device 8 via the supply pipe 40. Details of the delivery device 8 will be described later with reference to FIGS. 3 to 6. The supply pipe 41 is arranged obliquely with respect to the gravity direction, and the delivery device 8 is connected to the lower end of the supply pipe 41. The funnel 9 is arranged below a discharge port 410 near the upper end of the supply pipe 41 as being spaced apart from the discharge port 410. The funnel 9 is connected to the load lock chamber C2 via the supply pipes 42, 43. A valve V1 is connected between the supply pipes 42, 43.

The load lock chamber C2 is a container to contain the solid target substance 270 supplied from the solid target container C1. The temperature in the load lock chamber C2 is lower than the melting point of the target substance. The load lock chamber C2 is connected to the molten target container C3 via the supply pipes 44, 45. A valve V2 is connected between the supply pipes 44, 45.

### 2.1.2 Molten Target Container C3

The molten target container C3 contains the target substance supplied from the load lock chamber C2. The molten target container C3 is connected to the gas cylinder G1 via a pressurized gas pipe L0. The gas cylinder G1 contains a high-pressure rare gas such as an argon gas or a helium gas as a pressurized gas. The pressure regulator 56 and a pressure gauge P are arranged at the pressurized gas pipe L0. The target supply processor 55 controls the pressure regulator 56 based on an output of the pressure gauge P, so that the pressure in the molten target container C3 is adjusted to a predetermined pressure higher than the atmospheric pressure.

A heater 51 and a level sensor 54 are arranged at the molten target container C3. The heater 51 is connected to a power source (not shown) and heats the inside of the molten target container C3 to a predetermined temperature higher than the melting point of the target substance. The temperature in the molten target container C3 is controlled by controlling the power source based on an output of a temperature sensor (not shown) arranged at the molten target container C3. As a result, the solid target substance 270 is melted in the molten target container C3 to generate a molten target substance. The level sensor 54 detects liquid level position of the molten target substance in the molten target container C3.

### 2.1.3 Nozzle 52

The nozzle 52 is arranged at the lower end of the molten target container C3 in the gravity direction. The tip of the nozzle 52 is opened to the inside of the chamber 2 (see FIG. 1). A piezoelectric element 53 is arranged at the nozzle 52.

### 2.2 Operation of Droplet Target Generation Device 26

When the level sensor 54 detects that the liquid level position of the molten target substance in the molten target container C3 becomes below a threshold, the solid target substance 270 is replenished from the solid target container C1 as described below.

The target supply processor 55 opens the valve V1 with the valve V2 closed. Since the valve V2 is closed, the inside of the molten target container C3 is maintained at a high pressure. By opening the valve V1, the load lock chamber C2 is ready to receive the solid target substance 270.

The target supply processor 55 calculates the supply amount of the solid target substance 270 by the feed device 7 from the shortage amount of the molten target substance in the molten target container C3, and outputs a feed signal to the feed device 7. The feed device 7 feeds the solid target substance 270 to the supply pipe 40 one by one according to the feed signal. The target supply processor 55 does not output a subsequent feed signal until the replenishment of the solid target substance 270 to the molten target container C3 based on the latest feed signal is completed.

The delivery device 8 receives the solid target substance 270 from the supply pipe 40, and delivers the solid target substance 270 to the supply pipe 41 one by one at regular time intervals according to a control signal from the target supply processor 55.

The solid target substance 270 delivered from the delivery device 8 to the supply pipe 41 one by one is pressed by the solid target substance 270 delivered subsequently. As a result, the plurality of solid target substances 270 are successively moved in the supply pipe 41 against gravity, and drop into the funnel 9 from the discharge port 410 in order from the solid target substance 270 at the top. Owing to that the solid target substances 270 are delivered against gravity, the height of the entire EUV light generation system 11 including the solid target substance replenishment device 260 can be suppressed, and the degree of freedom in installation of the EUV light generation system 11 can be improved.

The solid target substance 270 having dropped from the discharge port 410 into the funnel 9 flows into the supply pipe 42. The solid target substance 270 moves to the load lock chamber C2 through the open valve V1 and the supply pipe 43. When a desired amount of the solid target substances 270 is moved to the load lock chamber C2, the target supply processor 55 stops operation of the feed device 7 and the delivery device 8 and closes the valve V1.

Next, the target supply processor 55 opens the valve V2 to replenish the solid target substance 270 contained in the load lock chamber C2 to the molten target container C3. The solid target substance 270 moves from the load lock chamber C2 to the molten target container C3. The solid target substance 270 supplied to the molten target container C3 melts and mixes with the target substance already contained and melted in the molten target container C3. The heater 51 suppresses a decrease in the internal temperature of the molten target container C3.

When the valve V2 is opened, a portion of the gas in the molten target container C3 moves to the load lock chamber C2, and the pressure inside the molten target container C3 temporarily decreases. Since the valve V1 is closed before opening the valve V2, the high-pressure gas in the molten target container C3 is prevented from flowing from the valve V1 toward the funnel 9. Further, the pressurized gas in the gas cylinder G1 is supplied to the molten target container C3 via the pressure regulator 56, whereby the pressure in the molten target container C3 is recovered.

The molten target substance in the molten target container C3 is output from the opening at the tip of the nozzle 52 owing to the pressure difference between the pressurized gas supplied from the pressure regulator 56 and the pressure in the chamber 2. When vibration is applied to the nozzle 52 by the piezoelectric element 53, the jet-like molten target substance output from the nozzle 52 is separated into droplets to form the target 27.

According to the comparative example, solid target substance 270 contained in the solid target container C1 having a substantially atmospheric pressure can be supplied into the molten target container C3 having a high pressure. Even when the target substance in the molten target container C3 is consumed, the target substance can be replenished without replacing the molten target container C3, so that the downtime of the EUV light generation apparatus 1 can be reduced.

### 2.3 Configuration of Delivery Device 8

FIGS. 3 to 6 show the configuration and operation of the delivery device 8 according to the comparative example. In FIGS. 3 to 6, the individual solid target substances 270 are denoted by reference signs α to ω, and the reference signs α to ω may be used to distinguish them. The delivery device 8 includes a tube 80, a delivery rod 81, a stopper 82, and a base portion 83.

The tube 80 has a cylindrical shape having a straight center axis, and includes a receiving port 801 for receiving the solid target substance 270 having passed through the feed device 7 and the supply pipe 40, and an entrance 802 facing the receiving port 801. The delivery rod 81 is located in the tube 80 and configured to deliver the solid target substance 270 in the tube 80 by being caused to alternately move forward and backward in the length direction of the tube 80 by a drive unit 84.

The direction of the forward movement of the delivery rod 81 is defined as an X direction, the direction in which the solid target substance 270 passes through the receiving port 801 is defined as a Z direction, and one of the directions perpendicular to the X direction and the Z direction is defined as a Y direction. FIGS. 3 to 6 are views of the delivery device 8 viewed in the −Y direction. The tube 80 is supported by the base portion 83 at an angle A with respect to the horizontal direction, and connected to the supply pipe 41 having a larger inclination. The drive unit 84 is supported by the base portion 83.

The stopper 82 includes a tapered portion 820 and a rod portion 824. The tapered portion 820 is supported by the rod portion 824, and the rod portion 824 is supported by the base portion 83 via a rotation shaft 825. The rotation shaft 825 is parallel to the Y direction, and the stopper 82 is movable while pivoting in a plane parallel to an XZ plane.

The tapered portion 820 passes through the entrance 802 of the tube 80. The tapered portion 820 includes a first surface 821 and a second surface 822. The first surface 821 is inclined with respect to the X direction, and the second surface 822 intersects the X direction at an angle closer to be perpendicular thereto than the angle between the X direction and the first surface 821.

The stopper 82 is provided with a counterclockwise rotational force in FIGS. 3 to 6 by the restoring force of the spring 826. When the delivery rod 81 moves forward in the X direction, the stopper 82 is pressed by the delivery rod 81 and pivots clockwise against the restoring force of the spring 826. When the delivery rod 81 is moved backward in the −X direction, the stopper 82 pivots counterclockwise by the restoring force of the spring 826, but when the stopper 82 abuts a stop pin 827, the counterclockwise pivot of the stopper 82 is restricted. At this time, as shown in FIG. 3, the stopper 82 restricts the solid target substance γ in the tube 80 from returning in the −X direction. A space for receiving the solid target substance β supplied from the receiving port 801 is secured between the receiving port 801 and the entrance 802.

### 2.4 Operation of Delivery Device 8

Referring to FIGS. 3 to 6, description is provided on the operation of the delivery device 8 to deliver the solid target substance β waiting in the supply pipe 40 to the supply pipe 41. As a result of the delivery device 8 delivering the plurality of solid target substances 270 one by one, as shown in FIG. 3, it is assumed that the solid target substances γ to ω are already filled in line in the tube 80 and the supply pipe 41. When the delivery rod 81 moves backward to its most retracted position in the −X direction, the solid target substance β moves into the space between the receiving port 801 and the entrance 802.

Thereafter, the delivery rod 81 moves in the X direction in the tube 80 and presses the first surface 821 of the stopper 82 via the solid target substance β between the receiving port 801 and the entrance 802. As shown in FIG. 4, the stopper 82 pressed by the delivery rod 81 pivots clockwise in FIG. 4 against the restoring force of the spring 826, and most of the tapered portion 820 moves to the outside of the tube 80. Thus, a passage for moving the solid target substance β in the X direction is formed in the tube 80.

The solid target substance β is pressed by the delivery rod 81 moving in the X direction while being pressed against the wall surface on the −Z direction side in the tube 80 by receiving the reaction force from the inclined first surface 821 of the stopper 82, and moves in the tube 80 as indicated by an arrow B in FIG. 4. The solid target substance β presses the solid target substances γ to ω. In this way, the delivery rod 81 delivers the solid target substances β to ω against gravity, causing the solid target substance ω to drop from the discharge port 410.

As the solid target substance β moves away from the first surface 821 by passing over the ridge line between the first surface 821 and the second surface 822 of the tapered portion 820, the stopper 82 pivots counterclockwise in FIG. 4 to the distal end position of the delivery rod 81 by the restoring force of the spring 826. That is, the passage of the solid target substance 270 in the tube 80 is maximized when the solid target substance β passes over the ridge line between the first surface 821 and the second surface 822 of the tapered portion 820, and thereafter the tapered portion 820 moves toward the inside of the tube 80.

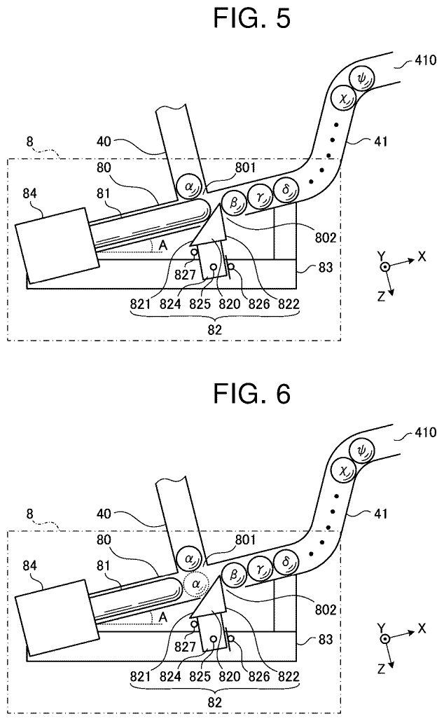

As shown in FIG. 5, when the delivery rod 81 starts moving in the −X direction, the stopper 82 pivots counterclockwise in FIG. 5 while being pressed against the delivery rod 81 by the restoring force of the spring 826, and the tapered portion 820 further moves toward the inside of the tube 80. At this time, since the solid target substance β cannot pass over the ridge line between the first surface 821 and the second surface 822, it cannot return to the space between the receiving port 801 and the entrance 802, and is in contact with the second surface 822. The counterclockwise pivot of the stopper 82 is stopped by the stop pin 827.

As shown in FIG. 6, when the delivery rod 81 is moved to the position most retracted in the −X direction, the solid target substance α waiting in the supply pipe 40 moves to the space between the receiving port 801 and the entrance 802.

Thereafter, by repeating the operation described with reference to FIGS. 3 to 6, the solid target substance 270 is delivered one by one to the supply pipe 41.

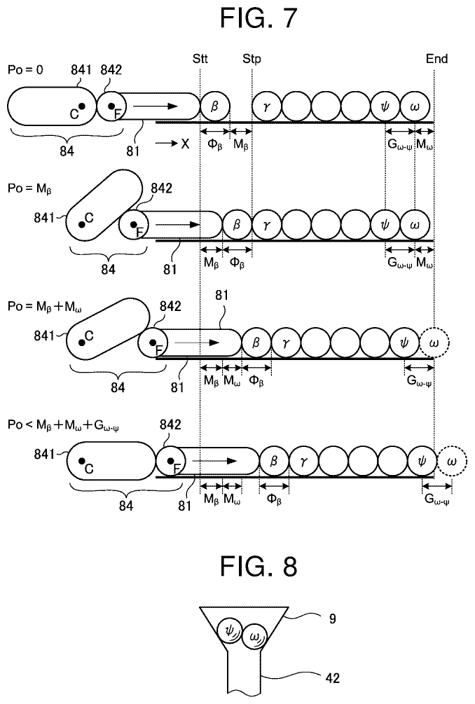

FIG. 7 shows how the solid target substances β to ω move in response to the reciprocal movement of the delivery rod 81. FIG. 7 shows a cam 841 and a cam follower 842 configuring the drive unit 84. The cam 841 includes a rotation axis C fixed at a constant position with respect to the base portion 83 (see FIG. 3), and is rotatable clockwise about the rotation axis C by a motor (not shown). The cam follower 842 includes a rotation axis F fixed to the rear end of the delivery rod 81, and is rotatable about the rotation axis F. The cam follower 842 is pressed by a cam surface of the cam 841 and moves forward in the X direction together with the delivery rod 81. The delivery rod 81 is pressed in the −X direction by a biasing mechanism (not shown), and is moved backward in the −X direction together with the cam follower 842 when the cam surface is retracted. Accordingly, the cam follower 842 is always in contact with the cam surface of the cam 841. Each time the cam 841 rotates once, the delivery rod 81 performs one reciprocal movement.

The distal end position of the delivery rod 81 when the delivery rod 81 is retracted most toward the −X direction side is defined as Stt. The position of the second surface 822 of the stopper 82 when the stopper 82 shown in FIG. 3 is abutted to the stop pin 827, that is, the rear end position of the solid target substance γ regulated by the stopper 82 is defined as Stp. The position of the discharge port 410 of the supply pipe 41 is defined as End. The positions Stt, Stp, End are constant regardless of the sizes and shapes of the solid target substances β to ω.

The particle size of the solid target substance β is defined as Φ_{β}. A gap between the solid target substances β, γ when the delivery rod 81 is retracted most toward the −X direction side is defined as an acceptance margin M_{β}. Although the solid target substances β, γ may have different particle sizes from each other, the difference in the particle sizes of the solid target substances β, γ is negligibly small in defining the acceptance margin M_{β}. The acceptance margin M_{β} is equal to a value obtained by subtracting the particle size Φ_{β} of the solid target substance β from the distance between the positions Stt, Stp.

The distance from the position of the centroid of the solid target substance ω when the delivery rod 81 is retracted most toward the −X direction side to the position End is defined as a standby margin Mo. The standby margin M_{ω} is equal to a value obtained by subtracting the sum of the particle sizes of the solid target substances γ to ψ and half of the particle size of the solid target substance ω from the distance between the positions Stp, End.

The inter-centroid distance between the centroids of the solid target substances ψ, ω is defined as G_{ω-ψ}. Although the solid target substances ψ, ω may have different particle sizes from each other, the difference in the particle sizes of the solid target substances ψ, ω is negligibly small in defining the inter-centroid distance G_{ω-ψ}.

The acceptance margin M_{β} depends on the particle size Φ_{β} of the solid target substance β, the standby margin M_{ω} depends on the particle sizes of the solid target substances γ to ω, and the inter-centroid distance G_{ω-ψ} depends on the particle sizes of the solid target substances ψ, ω. The solid target substances β to ω may not be perfect spheres, but the difference in the shapes between the solid target substances β to ω and a perfect sphere shall be negligible in defining the acceptance margin M_{β}, the standby margin M_{ω}, and the inter-centroid distance G_{ω-ψ}.

A displacement Po of the delivery rod 81 when the delivery rod 81 is retracted toward most toward the −X direction side is defined as 0 (Po=0). When the cam 841 rotates and the delivery rod 81 moves forward by M_{β} in the X direction (Po=M_{β}), the solid target substances β, γ contact to each other. Thereafter, when the delivery rod 81 moves forward in accordance with the rotation of the cam 841, the solid target substances β to ω move in the X direction.

When the cam 841 further rotates and the delivery rod 81 moves forward in the X direction by M_{β}+M_{ω} (Po=M_{β}+M_{ω}), the centroid of the solid target substance ω reaches the position End, and the solid target substance ω drops from the discharge port 410 into the funnel 9. Thereafter, when the delivery rod 81 moves forward in accordance with the rotation of the cam 841, the solid target substances β to ψ move in the X direction.

When the delivery rod 81 is advanced most in the X direction, if the displacement Po is less than M_{β}+M_{ω}+G_{ω-ψ} (Po<M_{β}+M_{ω}+G_{ω-ψ}), the centroid of the solid target substance ψ does not reach the position End, so that the solid target substance ψ remains inside the supply pipe 41. Thereafter, the delivery rod 81 moves backward in the −X direction in accordance with the rotation of the cam 841. In this case, one solid target substance ω is supplied toward the supply pipe 42 by one reciprocal movement of the delivery rod 81.

### 2.5 Problem of Comparative Example

FIG. 8 shows the funnel 9 and the supply pipe 42 for receiving the solid target substance 270 having dropped from the discharge port 410 and guiding the solid target substance 270 to the molten target container C3. The funnel 9 has a conical shape whose diameter decreases from the upper end toward the lower end. The lower end of the funnel 9 is connected to the supply pipe 42. The inner diameter of the lower end of the funnel 9 is approximately equal to the inner diameter of the supply pipe 42, is larger than the average particle size of the solid target substances 270 contained in the solid target container C1, and is smaller than twice the average particle size. Therefore, two or more solid target substances 270 cannot pass through the supply pipe 42 at the same time, and the solid target substance 270 passes through the supply pipe 42 one by one.

The solid target substance 270 having dropped into the funnel 9 moves toward the lower end of the funnel 9 by gravity. If the movement direction of the solid target substance 270 having dropped into the funnel 9 has a rotational direction component about the center axis of the funnel 9, the solid target substance 270 receives a reaction force having a direction component opposite to gravity from the inner surface of the funnel 9 in response to the centrifugal force thereof. At this time, the solid target substance 270 moves spirally along the inner surface of the funnel 9, and it may take a long time to reach the lower end of the funnel 9.

If the subsequent solid target substance ψ drops into the funnel 9 before the solid target substance ω reaches the lower end of the funnel 9, the two solid target substances ω, ψ may come into contact at the vicinity of the lower end of the funnel 9, restrict mutual downward movement, and clogging may occur. Therefore, the required time for one reciprocal movement of the delivery rod 81 needs to be set sufficiently long so that the solid target substance ψ drops into the funnel 9 with a sufficient time interval after the solid target substance ω drops into the funnel 9.

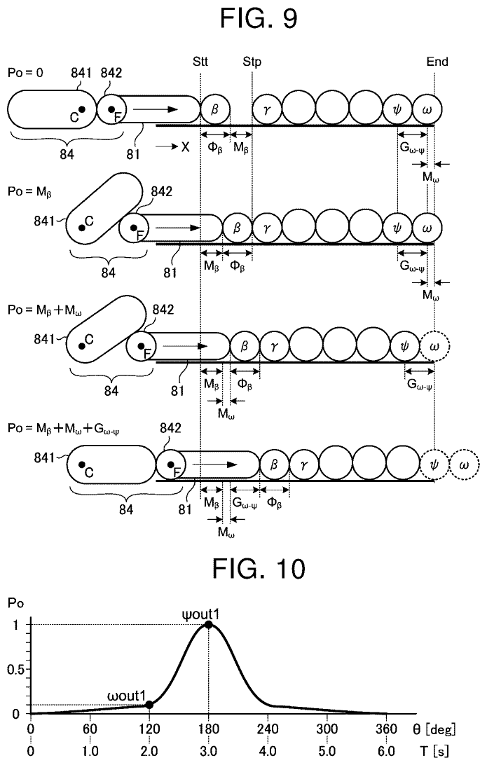

However, one reciprocal movement of the delivery rod 81 may cause a plurality of the solid target substances ω, ψ to drop into the funnel 9. This will be described with reference to FIGS. 9 to 12.

FIG. 9 shows a first example in which two solid target substances ω, ψ drop into the funnel 9 by one reciprocal movement of the delivery rod 81. In FIG. 9, the acceptance margin M_{β} and the inter-centroid distance G_{ω-ψ} are similar to those in FIG. 7, but the standby margin M_{ω} is smaller than that in FIG. 7. Therefore, the value of M_{β}+M_{ω} is smaller than that in FIG. 7. That is, the solid target substance ω drops faster than in FIG. 7.

In FIG. 9, the value of M_{β}+M_{ω}+G_{ω-ψ} is also smaller than that in FIG. 7. When the displacement Po reaches M_{β}+M_{ω}+G_{ω-ψ} by the time when the delivery rod 81 is advanced most in the X direction (Po=M_{β}+M_{ω}+G_{ω-ψ}), the centroid of the solid target substance ψ reaches the position End, and the solid target substance ψ drops. Thus, the two solid target substances ω, ψ drop into the funnel 9 by one reciprocal movement of the delivery rod 81.

FIG. 10 is a graph showing drop timing of the solid target substances ω, ψ in the first example together with a cam curve of the cam 841. The horizontal axis represents a rotation angle θ of the cam 841 and a time T when the cam 841 rotates at a constant speed. The maximum value of the time T corresponds to the required time for one reciprocal movement of the delivery rod 81, and is 6.0 seconds in FIG. 10. The vertical axis represents the displacement Po of the delivery rod 81 due to the movement of the cam 841 as being normalized to have a maximum value of 1. Positions on the cam curve corresponding to the drop timing of the solid target substances ω, ψ are represented by ωout1 and ψout1, respectively.

In FIG. 10, the solid target substance ω drops at ωout1 where the displacement Po is 0.1 and the time T is 2.0 seconds, and the solid target substance ψ drops at ψout1 where the displacement Po is 1.0 and the time T is 3.0 seconds. Even if the difference in the displacement Po between those at ωout1 and ψout1 is as large as 0.9, the difference in the time T is only 1.0 second.

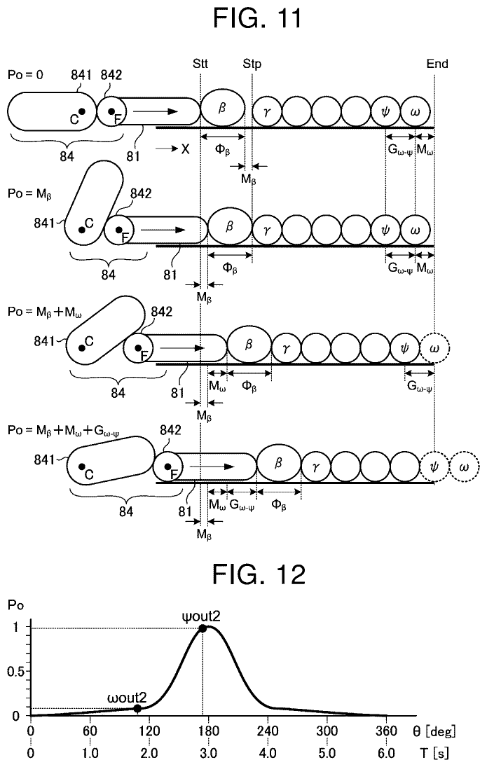

FIG. 11 shows a second example in which two solid target substances ω, v drop into the funnel 9 by one reciprocal movement of the delivery rod 81. In FIG. 11, the standby margin Mβ and the inter-centroid distance Gω-ψ are similar to those in FIG. 7, but the acceptance margin Mω is smaller than that in FIG. 7. Therefore, the value of M_{β}+M_{ω} and the value of M_{β}+M_{ω}+G_{ω-ψ} are smaller than those in FIG. 7. When the displacement Po reaches M_{β}+M_{ω} (Po=M_{β}+M_{ω}), the solid target substance ω drops.

When the displacement Po reaches M_{β}+M_{ω}+G_{ω-ψ} (Po=M_{β}+M_{ω}+G_{ω-ψ}) before the delivery rod 81 advances most in the X direction, the solid target substance ψ also drops. Thus, the two solid target substances ω, ψ drop into the funnel 9 by one reciprocal movement of the delivery rod 81.

FIG. 12 is a graph showing the drop timing of the solid target substances ω, ψ in the second example together with the cam curve of the cam 841. Definitions of the horizontal axis and the vertical axis and the cam curve are the same as those in FIG. 10. Positions on the cam curve corresponding to the drop timing of the solid target substances ω, ψ are represented by ωout2 and ψout2, respectively.

In FIG. 12, the solid target substance ω drops at ωout2 where the displacement Po is 0.08 and the time T is 1.8 seconds, and the solid target substance ψ drops at ψout2 where the displacement Po is 0.98 and the time T is 2.9 seconds. Even if the difference in the displacement Po between those at ωout2 and ψout2 is as large as 0.9, the difference in the time T is only 1.1 seconds.

The embodiments described below relate to suppressing occurrence of clogging in the funnel 9 and stably replenishing the solid target substance 270 even when a plurality of the solid target substances 270 drop into the funnel 9 by one reciprocal movement of the delivery rod 81.

### 3. Solid Target Substance Replenishment Device 260 with Drop Time Difference T_{ψ}-t_{ω} Longer than 1.1 Seconds

### 3.1 Configuration of Cam 841a

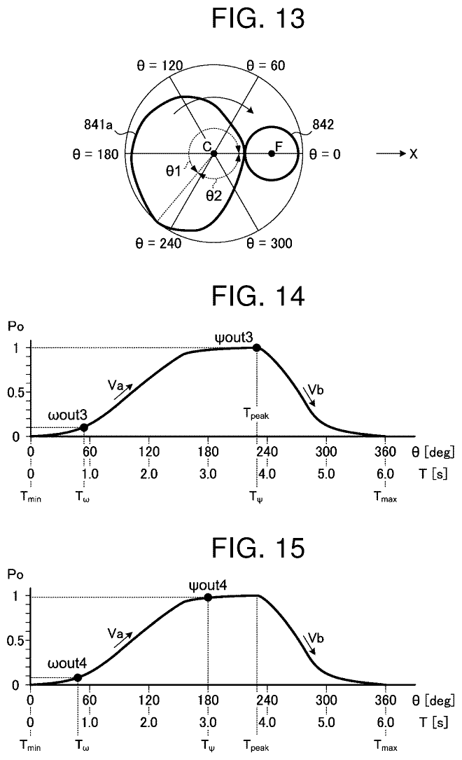

FIG. 13 shows the configuration of a cam 841a and the cam follower 842 of a first embodiment. In FIG. 13, the cam follower 842 is in contact with a portion of a cam surface of the cam 841a where θ=0°, which is a portion having the shortest distance from the rotation axis C. When the cam 841a rotates clockwise, the cam follower 842 moves forward along an extension of a line segment connecting the rotation axes C, F.

A portion of the cam surface of the cam 841a having the longest distance from the rotation axis C is located at a portion where θ>180°. Therefore, a first rotation angle θ1 of the cam 841a causing the forward movement of the delivery rod 81 is larger than a second rotation angle θ2 of the cam 841a causing the backward movement of the delivery rod 81. The first rotation angle θ1 may be smaller than three times the second rotation angle θ2. The first and second rotation angles θ1, θ2 are, for example, 230° and 130°, respectively.

### 3.2 Cam Curve of Cam 841a

FIG. 14 is a graph showing the drop timing of the solid target substances ω, ψ in the first example in the first embodiment together with the cam curve of the cam 841a. Definitions of the horizontal axis and the vertical axis are the same as those in FIG. 10. The time T corresponding to the peak position of the cam curve is defined as a peak time Tₚₑₐₖ. The time T corresponding to the rotation angle θ=0 of the cam 841a is defined as a start time Tₘᵢₙ, and the start time Tₘᵢₙ is 0 seconds. The required time of one rotation of the cam 841a, that is, the required time of one reciprocal movement of the delivery rod 81 is defined as a rotation cycle Tₘₐₓ, and the rotation cycle Tₘₐₓ is preferably longer than 3.0 seconds and shorter than 12.0 seconds.

The required time Tₚₑₐₖ−Tₘᵢₙ of the forward movement of the delivery rod 81 is longer than the required time Tₘₐₓ−Tₚₑₐₖ of the backward movement. The required time Tₚₑₐₖ−Tₘᵢₙ of the forward movement may be shorter than three times the required time Tₘₐₓ−Tₚₑₐₖ of the backward movement. When the peak position of the cam curve where the displacement Po is 1 is at the position of θ=230°, each of the peak time Tₚₑₐₖ and the required time Tₚₑₐₖ−Tₘᵢₙ of the forward movement is about 3.8 seconds. When the rotation cycle Tₘₐₓ is 6.0 seconds, the required time Tₘₐₓ−Tₚₑₐₖ of the backward movement is about 2.2 seconds.

The slope of the cam curve corresponds to the velocity of the reciprocal movement of the delivery rod 81. Among the forward movement which takes about 3.8 seconds, the velocity is small in about the first 1 second and about the last 1 second, and the velocity is larger in about 1.8 seconds in the middle than in the first and last. Further, when the maximum values of the absolute values of the velocity of the forward movement and the backward movement is defined as Va and Vb, respectively, the drive unit 84 reciprocates the delivery rod 81 so that Va is smaller than Vb. The drive unit 84 may reciprocate the delivery rod 81 so that Va is larger than one third of Vb. Preferably, Va is larger than 0.5 mm/s and smaller than 4.0 mm/s.

In FIG. 14, the acceptance margin M_{β} and the standby margin M_{ω} are similar to those in FIGS. 9 and 10, and it is assumed that the two solid target substances ω, ψ drop into the funnel 9 by one reciprocal movement of the delivery rod 81. In this case, the solid target substance ω drops at ωout3 when the displacement Po is 0.1 and the time T is 0.9 seconds, and the solid target substance ψ drops at ψout3 when the displacement Po is 1.0 and the time T is about 3.8 seconds.

The time difference T_{ψ}−T_{ω} is about 2.9 seconds.

FIG. 15 is a graph showing the drop timing of the solid target substances ω, ψ in the second example in the first embodiment together with the cam curve of the cam 841a. Definitions of the horizontal axis and the vertical axis are the same as those in FIG. 10, and the cam curve is the same as that in FIG. 14.

In FIG. 15, the acceptance margin M_{β} and the standby margin M_{ω} are similar to those in FIGS. 11 and 12, and it is assumed that the two solid target substances ω, ψ drop into the funnel 9 by one reciprocal movement of the delivery rod 81. In this case, the solid target substance ω drops at ωout4 where the displacement Po is 0.08 and the time T is 0.8 seconds, and the solid target substance drops at ψout4 where the displacement Po is 0.98 and the time T is about 3.0 seconds. The time difference T_{ψ}−T_{ω} is about 2.2 seconds.

Although the time difference T_{ψ}−T_{ω} is not limited to the length shown in FIGS. 14 and 15, the time difference T_{ψ}−T_{ω} is preferably longer than one fifth of the rotation cycle Tₘₐₓ. The time difference T_{ψ}−T_{ω} is preferably longer than 1.1 seconds and shorter than 8.0 seconds. Although the case in which the cam 841a rotates at a constant speed has been described, the time difference T_{ψ}−T_{ω}, the required time Tₚₑₐₖ−Tₘᵢₙ of the forward movement, the rotation cycle Tₘₐₓ, and the like may be controlled as changing the rotation speed.

The difference in the displacement Po between those at ωout3 and ψout3 in FIG. 14 and the difference in the displacement Po between those at ωout4 and ψout4 in FIG. 15 are both 0.9, but these values vary depending on the inter-centroid distance G_{ω-ψ} of the solid target substances ψ, ω. If a movement distance L of the forward movement of the delivery rod 81 is too long with respect to the inter-centroid distance G_{ω-ψ}, there is a high possibility that two or more solid target substances 270 drop by one reciprocal movement. Further, if the movement distance L is too short, there is a high possibility that the solid target substance 270 will not drop even when the delivery rod 81 moves forward. When the average particle size of the solid target substances 270 contained in the solid target container C1 is defined as D, the movement distance L of the forward movement of the delivery rod 81 is preferably in the range of 1.05 D<L<1.6 D.

### 3.3 Effect

(1) According to the first embodiment, the solid target substance replenishment device 260 includes the solid target container C1, the feed device 7, the supply pipe 40, the delivery device 8, the supply pipe 41, and the funnel 9. The solid target container C1 contains the solid target substance 270. The solid target substance 270 supplied from the solid target container C1 passes through the feed device 7 and the supply pipe 40. The delivery device 8 includes the tube 80 that receives the solid target substance 270 having passed through the feed device 7 and the supply pipe 40, the delivery rod 81 that delivers the solid target substance 270 in the tube 80 in the X direction that is the length direction of the tube 80, and the drive unit 84 that reciprocates the delivery rod 81 in the X direction and the −X direction that is the length direction of the tube 80. The solid target substance 270 delivered by the delivery device 8 passes through the supply pipe 41. The funnel 9 guides, to the EUV light generation apparatus 1, the solid target substance 270 having passed through the supply pipe 41 and having dropped to the molten target container C3. The drive unit 84 drives the delivery rod 81 so that the time difference T_{ψ}−T_{ω} of the drop is longer than 1.1 seconds when two or more solid target substances 270 drop from the supply pipe 41 into the funnel 9 by one reciprocal movement of the delivery rod 81.

Accordingly, by increasing the drop time difference T_{ψ}−T_{ω}, clogging in the funnel 9 can be suppressed, and the solid target substance 270 can be stably supplied to the molten target container C3.

(2) According to the first embodiment, the drive unit 84 reciprocates the delivery rod 81 so that the required time Tₚₑₐₖ−Tₘᵢₙ of the forward movement of the reciprocal movement of the delivery rod 81 toward the supply pipe 41 is longer than the required time Tₘₐₓ−Tₚₑₐₖ of the backward movement thereof in the direction opposite to the forward movement.

Accordingly, the drop time difference T_{ψ}−T_{ω} can be made longer with the forward movement taking more time than the backward movement.

(3) According to the first embodiment, the drive unit 84 reciprocates the delivery rod 81 so that the required time Tₚₑₐₖ−Tₘᵢₙ of the forward movement is shorter than three times the required time Tₘₐₓ−Tₚₑₐₖ of the backward movement.

Accordingly, not only the required time Tₚₑₐₖ−Tₘᵢₙ Of the forward movement but also the required time Tₘₐₓ−Tₚₑₐₖ Of the backward movement are sufficiently secured, so that the delivery device 8 can be operated smoothly.

(4) According to the first embodiment, the drive unit 84 includes the cam 841a and the cam follower 842, and the first rotation angle θ1 of the cam 841a causing the forward movement of the reciprocal movement of the delivery rod 81 toward the supply pipe 41 is larger than the second rotation angle θ2 of the cam 841a causing the backward movement thereof in the direction opposite to the forward movement.

Accordingly, for example, when the cam 841a is rotated at a constant speed, the required time Tₚₑₐₖ−Tₘᵢₙ Of the forward movement can be made longer than the required time Tₘₐₓ−Tₚₑₐₖ of the backward movement, so that the drop time difference T_{ψ}−T_{ω} can be made longer.

(5) According to the first embodiment, the first rotation angle θ1 is smaller than three times the second rotation angle θ2.

Accordingly, for example, when the cam 841a is rotated at a constant speed, since not only the required time Tₚₑₐₖ−Tₘᵢₙ of the forward movement but also the required time Tₘₐₓ−Tₚₑₐₖ of the backward movement are sufficiently secured, the delivery device 8 can be operated smoothly.

(6) According to the first embodiment, the drive unit 84 reciprocates the delivery rod 81 so that the maximum value Va of the absolute value of the velocity of the forward movement of the reciprocal movement of the delivery rod 81 toward the supply pipe 41 is smaller than the maximum value Vb of the absolute value of the velocity of the backward movement thereof in the direction opposite to the forward movement.

Accordingly, the drop time difference T_{ψ}−T_{ω} can be made longer by making the forward movement slower than the backward movement.

(7) According to the first embodiment, the drive unit 84 reciprocates the delivery rod 81 so that the maximum value Va of the absolute value of the velocity of the forward movement is smaller than one third of the maximum value Vb of the absolute value of the velocity of the backward movement.

Accordingly, not only the velocity of the forward movement but also the velocity of the backward movement is prevented from being too fast, so that the delivery device 8 can be operated smoothly.

(8) According to the first embodiment, the drive unit 84 reciprocates the delivery rod 81 so that the maximum value Va of the absolute value of the velocity of the forward movement of the reciprocal movement of the delivery rod 81 toward the supply pipe 41 is larger than 0.5 mm/s and smaller than 4.0 mm/s.

Accordingly, by making Va faster than 0.5 mm/s, the delivery amount of the solid target substance 270 per unit time can be sufficiently secured. By making Va slower than 4.0 mm/s, the drop time difference T_{ψ}−T_{ω} can be made longer.

(9) According to the first embodiment, the drive unit 84 drives the delivery rod 81 so that the drop time difference T_{ψ}−T_{ω} is longer than one fifth of the required time of one reciprocal movement of the delivery rod 81.

Accordingly, by increasing the drop time difference T_{ψ}−T_{ω}, it is possible to suppress the clogging in the funnel 9.

(10) According to the first embodiment, the drive unit 84 drives the delivery rod 81 so that the drop time difference T_{ψ}−T_{ω} is shorter than 8.0 seconds.

Accordingly, it is possible to secure the replenishment amount of the solid target substance 270 per unit time by preventing the drop time difference T_{ψ}−T_{ω} from becoming too long.

(11) According to the first embodiment, the drive unit 84 drives the delivery rod 81 so that the required time of one reciprocal movement of the delivery rod 81 is longer than 3.0 seconds.

Accordingly, by making the required time of one reciprocal movement longer than 3.0 seconds, it is possible to prevent the drop time difference T_{ψ}−T_{ω} from becoming too short.

(12) According to the first embodiment, the drive unit 84 drives the delivery rod 81 so that the required time of one reciprocal movement of the delivery rod 81 is shorter than 12.0 seconds.

Accordingly, by making the required time of one reciprocal movement shorter than 12.0 seconds, the number of the solid target substance 270 delivered per unit time can be sufficiently secured.

(13) According to the first embodiment the movement distance L of the forward movement of the reciprocal movement of the delivery rod 81 toward the supply pipe 41 is shorter than 1.6 times the average particle size D of the solid target substances 270 contained in the solid target container C1.

Accordingly, by making the movement distance L of the reciprocal movement of the delivery rod 81 not too long with respect to the average particle size D of the solid target substance 270, it is possible to suppress two or more solid target substances 270 from dropping by one reciprocal movement.

(14) According to the first embodiment, the movement distance L of the forward movement of the delivery rod 81 is larger than 1.05 times the average particle size D of the solid target substances 270 contained in the solid target container C1.

Accordingly, the solid target substance 270 can be smoothly delivered by sufficiently securing the movement distance L of the forward movement of the delivery rod 81.

In other respects, the first embodiment is similar to the comparative example.

### 4. Solid Target Substance Replenishment Device 260c Including Detector D2

### 4.1 Configuration

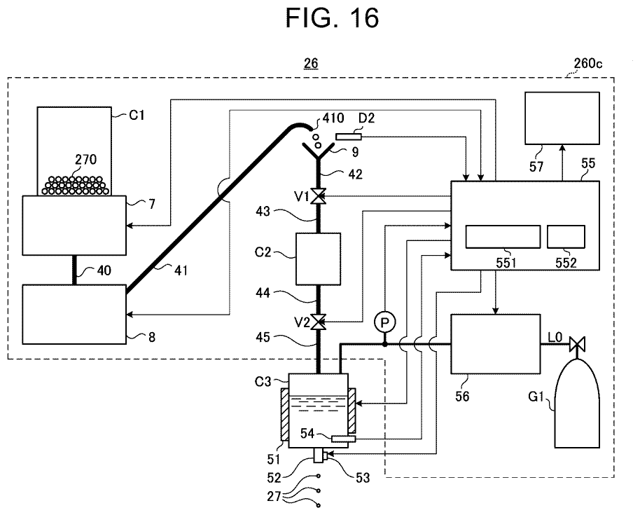

FIG. 16 shows the configuration of the droplet target generation device 26 of a second embodiment. In the second embodiment, a solid target substance replenishment device 260c includes a detector D2 and a display unit 57.

The detector D2 is arranged in the vicinity of the discharge port 410. The detector D2 may detect light output from a light source (not shown) and reflected by the solid target substance 270. The display unit 57 is a device that displays information in a visually recognizable manner, and may be an image display device or a light emitting element.

### 4.2 Operation

The second detector D2 transmits a detection signal to the target supply processor 55 each time one solid target substance 270 drops from the discharge port 410. The target supply processor 55 controls the drive unit 84 such that the time differences between the detection signals is longer than 1.1 seconds based on the detection signal.

The target supply processor 55 outputs an error signal when the time difference between the detection signals detected by the detector D2 is equal to or shorter than 1.1 seconds. The display unit 57 displays a warning in response to the error signal.

### 4.3 Effect

(15) According to the second embodiment, the solid target substance replenishment device 260c includes the detector D2 that detects the solid target substance 270 dropping from the supply pipe 41, and the target supply processor 55 that controls, based on the detection result of the detector D2, the drive unit 84 so that the drop time difference T_{ψ}−T_{ω} is equal to or longer than 1.1 seconds.

Accordingly, by controlling the drive unit 84 based on the detection result of the detector D2, it is possible to enhance the reliability of the control so that the drop time difference T_{ψ}−T_{ω} exceeds 1.1 seconds.

(16) According to the second embodiment, the solid target substance replenishment device 260c includes the detector D2 that detects the solid target substance 270 dropping from the supply pipe 41, and the target supply processor 55 that outputs the error signal when the time difference detected by the detector D2 is equal to or shorter than 1.1 seconds.

Accordingly, based on the error signal, it is possible to take measures such as stopping the delivery device 8 or slowing the reciprocal movement of the delivery rod 81.

(17) According to the second embodiment, the solid target substance replenishment device 260c includes the display unit 57 that displays an alert in response to the error signal.

Accordingly, it is possible to notify a user of the EUV light generation apparatus 1 of an error by displaying the warning.

In other respects, the second embodiment is similar to the first embodiment.

### 5. Others

### 5.1 EUV Light Utilization Apparatus 6

FIG. 17 shows the configuration of the exposure apparatus 6a connected to the EUV light generation system 11. In FIG. 17, the exposure apparatus 6a as the EUV light utilization apparatus 6 (see FIG. 1) includes a mask irradiation unit 608 and a workpiece irradiation unit 609. The mask irradiation unit 608 illuminates, via a reflection optical system, a mask pattern of a mask table MT with the EUV light incident from the EUV light generation system 11. The workpiece irradiation unit 609 images the EUV light reflected by the mask table MT onto a workpiece (not shown) arranged on a workpiece table WT via a reflection optical system. The workpiece is a photosensitive substrate such as a semiconductor wafer on which photoresist is applied. The exposure apparatus 6a synchronously translates the mask table MT and the workpiece table WT to expose the workpiece to the EUV light reflecting the mask pattern. Through the exposure process as described above, a device pattern is transferred onto the semiconductor wafer, thereby an electronic device can be manufactured.

FIG. 18 shows the configuration of the inspection apparatus 6b connected to the EUV light generation system 11. In FIG. 18, the inspection apparatus 6b as the EUV light utilization apparatus 6 (see FIG. 1) includes an illumination optical system 603 and a detection optical system 606. The illumination optical system 603 reflects the EUV light incident from the EUV light generation system 11 to illuminate a mask 605 placed on a mask stage 604. Here, the mask 605 conceptually includes a mask blanks before a pattern is formed. The detection optical system 606 reflects the EUV light from the illuminated mask 605 and forms an image on a light receiving surface of a detector 607. The detector 607 having received the EUV light obtains the image of the mask 605. The detector 607 is, for example, a time delay integration (TDI) camera. A defect of the mask 605 is inspected based on the image of the mask 605 acquired by the above-described process, and a mask suitable for manufacturing an electronic device is selected using the inspection result. Then, the electronic device can be manufactured by exposing and transferring the pattern formed on the selected mask onto the photosensitive substrate using the exposure apparatus 6a.

### 5.2 Supplement

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that the embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of any thereof and any other than A, B, and C.

What is claimed is:

1. A solid target substance replenishment device, comprising;
a solid target container configured to contain a solid target substance;
a first path through which the solid target substance supplied from the solid target container passes;
a delivery device including a tube that receives the solid target substance having passed through the first path, a delivery rod that delivers the solid target substance in the tube in a length direction of the tube, and a drive unit that reciprocates the delivery rod in the length direction of the tube;
a second path through which the target solid substance delivered by the delivery device passes; and
a funnel that guides, to a molten target container of an extreme ultraviolet light generation apparatus, the solid target substance having dropped after passing through the second path,
the drive unit driving the delivery rod so that drop time difference is longer than 1.1 seconds when two or more solid target substances drop from the second path into the funnel by one reciprocal movement of the delivery rod.

2. The solid target substance replenishment device according to claim 1,
wherein the drive unit reciprocates the delivery rod so that a required time of forward movement of the reciprocal movement of the delivery rod toward the second path is longer than a required time of backward movement in a direction opposite to the forward movement.

3. The solid target substance replenishment device according to claim 2,
wherein the drive unit reciprocates the delivery rod so that the required time of the forward movement is shorter than three times the required time of the backward movement.

4. The solid target substance replenishment device according to claim 1,
wherein the drive unit sa cam and a cam follower, and
a first rotation angle of the cam causing forward movement of the reciprocal movement of the delivery rod toward the second path is larger than a second rotation angle of the cam causing backward movement in a direction opposite to the forward movement.

5. The solid target substance replenishment device according to claim 4,
wherein the first rotation angle is smaller than three times the second rotation angle.

6. The solid target substance replenishment device according to claim 1,
wherein the drive unit reciprocates the delivery rod so that a maximum value of an absolute value of a velocity of forward movement of the delivery rod toward the second path is smaller than a maximum value of an absolute value of a velocity of backward movement in a direction opposite to the forward movement.

7. The solid target substance replenishment device according to claim 6,
wherein the drive unit reciprocates the delivery rod so that the maximum value of the absolute value of the velocity of the forward movement is larger than one third of the maximum value of the absolute value of the velocity of the backward movement.

8. The solid target substance replenishment device according to claim 1,
wherein the drive unit reciprocates the delivery rod so that a maximum value of an absolute value of a velocity of forward movement of the reciprocal movement of the delivery rod toward the second path is larger than 0.5 mm/s and smaller than 4.0 mm/s.

9. The solid target substance replenishment device according to claim 1,
wherein the drive unit drives the delivery rod so that the drop time difference is longer than one fifth of a required time of the reciprocal movement of one time.

10. The solid target substance replenishment device according to claim 1,
wherein the drive unit drives the delivery rod so that the drop time difference is shorter than 8.0 seconds.

11. The solid target substance replenishment device according to claim 1,
wherein the drive unit drives the delivery rod so that a required time of the reciprocal movement of one time is longer than 3.0 seconds.

12. The solid target substance replenishment device according to claim 11,
wherein the drive unit drives the delivery rod so that the required time of the reciprocal movement of one time is shorter than 12.0 seconds.

13. The solid target substance replenishment device according to claim 1,
wherein a movement distance of forward movement of the reciprocal movement of the delivery rod toward the second path is smaller than 1.6 times an average particle size of the solid target substances contained in the solid target container.

14. The solid target substance replenishment device according to claim 13,
wherein the movement distance is larger than 1.05 times the average particle size.

15. The solid target substance replenishment device according to claim 1, further comprising:
a detector configured to detect the solid target substance dropping from the second path; and
a processor configured to control the drive unit based on a detection result of the detector so that the drop time difference is longer than 1.1 seconds.

16. The solid target substance replenishment device according to claim 1, further comprising:
a detector configured to detect the solid target substance dropping from the second path; and
a processor configured to output an error signal when the drop time difference detected by the detector is equal to or shorter than 1.1 seconds.

17. The solid target substance replenishment device according to claim 16,
further comprising a display unit configured to display a warning in response to the error signal.

18. An extreme ultraviolet light generation apparatus comprising:
the solid target substance replenishment device according to claim 1,
the molten target container configured to melt the solid target substance replenished by the solid target substance replenishment device to produce a molten target substance;
a nozzle configured to output the molten target substance produced in the molten target container;
a laser device configured to irradiate, with pulse laser light, the molten target substance reaching a redetermined region after being output from the nozzle; and
an EUV light concentrating mirror configured to concentrate extreme ultraviolet light emitted from plasma generated in the predetermined region.

19. An electronic device manufacturing method, comprising:
generating extreme ultraviolet light using an extreme ultraviolet light generation apparatus;
outputting the extreme ultraviolet light to an exposure apparatus; and
exposing a photosensitive substrate to the extreme ultraviolet light in the exposure apparatus to manufacture an electronic device,
the extreme ultraviolet generation apparatus including:
a solid target substance replenishment device;
a molten target container configured to melt a solid target substance replenished by the solid target substance replenishment device to produce a molten target substance;
a nozzle configured to output the molten target substance produced in the molten target container;
a laser device configured to irradiate, with pulse laser light, the molten target substance reaching a redetermined region after being output from the nozzle; and
an EUV light concentrating mirror configured to concentrate extreme ultraviolet light emitted from plasma generated in the predetermined region,
the solid target substance replenishment device including:
a solid target container configured to contain the solid target substance;
a first path through which the solid target substance supplied from the solid target container passes;
a delivery device including a tube that receives the solid target substance having passed through the first path, a delivery rod that delivers the solid target substance inside the tube in a length direction of the tube, and a drive unit that reciprocates the delivery rod in the length direction of the tube;
a second path through which the solid target substance delivered by the delivery device passes; and
a funnel that guides, to the molten target container of an extreme ultraviolet light generation apparatus, the solid target substance having dropped after passing through the second path, and
the drive unit driving the delivery rod so that drop time difference is longer than 1.1 seconds when two or more solid target substances drop from the second path into the funnel by one reciprocal movement of the delivery rod.

20. An electronic device manufacturing method, comprising:
inspecting a defect of a mask by irradiating the mask with extreme ultraviolet light generated by an extreme ultraviolet light generation apparatus;
selecting a mask using a result of the inspection; and
exposing and transferring a pattern formed on the selected mask onto a photosensitive substrate,
the extreme ultraviolet generation apparatus including:
a solid target substance replenishment device;
a molten target container configured to melt a solid target substance replenished by the solid target substance replenishment device to produce a molten target substance;
a nozzle configured to output the molten target substance produced in the molten target container;
a laser device configured to irradiate, with pulse laser light, the molten target substance reaching a redetermined region after being output from the nozzle; and
an EUV light concentrating mirror configured to concentrate extreme ultraviolet light emitted from plasma generated in the predetermined region,
the solid target substance replenishment device including:
a solid target container configured to contain the solid target substance;
a first path through which the solid target substance supplied from the solid target container passes;
a delivery device including a tube that receives the solid target substance having passed through the first path, a delivery rod that delivers the solid target substance inside the tube in a length direction of the tube, and a drive unit that reciprocates the delivery rod in the length direction of the tube;
a second path through which the solid target substance delivered by the delivery device passes; and
a funnel that guides, to the molten target container of an extreme ultraviolet light generation apparatus, the solid target substance having dropped after passing through the second path, and
the drive unit driving the delivery rod so that drop time difference is longer than 1.1 seconds when two or more solid target substances drop from the second path into the funnel by one reciprocal movement of the delivery rod.
